(19) United States
(12) Patent Application Publication
(10) Pub. No.: US 2021/0296533 A1
(43) Pub. Date: Sep. 23, 2021

(54) SPHERICAL VERTICAL MICRO LED AND MANUFACTURING METHOD THEREOF, DISPLAY PANEL, AND TRANSFER METHOD FOR DISPLAY PANEL

(71) Applicant: CHONGQING KONKA PHOTOELECTRIC TECHNOLOGY RESEARCH INSTITUTE C., LTD., Chongqing (CN)

(72) Inventors: Biao TANG, Chongqing (CN); Haiping LIU, Chongqing (CN)

(21) Appl. No.: 17/203,329

(22) Filed: Mar. 16, 2021

(30) Foreign Application Priority Data
Mar. 23, 2020 (CN) 202010208376.7

(51) Int. Cl. H01L 33/24; H01L 33/38; H01L 33/00; H01L 25/075; H01L 21/67

(52) U.S. Cl. CPC H01L 33/24; H01L 33/38; H01L 33/0093; H01L 33/44; H01L 33/0075; H01L 21/67144; H01L 25/0753

(57) ABSTRACT

A spherical vertical micro light-emitting diode (LED) is provided. The spherical vertical micro LED includes a first semiconductor layer, a second semiconductor layer, a light-emitting layer disposed between the first semiconductor layer and the second semiconductor layer, a first electrode covered on at least part of a surface of the first semiconductor layer, a second electrode covered on at least part of a surface of the second semiconductor layer, and an insulating layer covered on an outside surface of the light-emitting layer, or covered on the outside surface of the light-emitting layer as well as part of the surface of the first semiconductor layer and part of the surface of the second semiconductor layer. The first semiconductor layer, the second semiconductor layer, and the light-emitting layer form a sphere structure. The first electrode, the second electrode, and the insulating layer form a spherical structure.

### CROSS-REFERENCE TO RELATED APPLICATION(S)

This application claims priority to Chinese Patent Application No. 202010208376.7, filed on Mar. 23, 2020, the disclosure of which is hereby incorporated by reference in its entirety.

### TECHNICAL FIELD

This disclosure relates to the field of display technologies and light-emitting diode (LED) technologies, and particularly to a spherical vertical micro LED and a manufacturing method thereof, a spherical vertical micro LED display panel, and a transfer method for the spherical vertical micro LED display panel.

### BACKGROUND

MicroLED, also known as micro LED, is an important component of a new generation of display technology. Compared to the existing liquid crystal display (LCD), the micro LED has a more ideal photoelectric efficiency, brightness, and contrast as well as lower power consumption. Moreover, the micro LED can be combined with a flexible panel to achieve flexible display. Based on the above advantages of the micro LED, the micro LED has been regarded as an important display technology of next generation.

In order to realize a display function, multiple micro LEDs need to be loaded on a backplane to form a micro-LED array. Mass transfer is a critical technology for forming the micro-LED array. At present, the mass transfer mainly includes electrostatic transfer, microprinting, and fluidic assembly. For the fluidic assembly, micro LEDs can be placed in a liquid suspension by rolling of a brush bucket on a substrate, and then the micro LEDs can sink into loading wells of the substrate under action of a fluid force.

However, the existing micro LED generally has a cuboid structure or a cylindrical structure. During loading the micro LED to the loading well of the substrate, the micro LED is often unable to accurately align with the loading well due to limitation of its shape, which in turn results in the micro LED not being embedded in the loading well, thus limiting a transfer yield and a production efficiency to a large extent.

In sum, the existing technology needs to be improved and developed.

### SUMMARY

A spherical vertical micro light-emitting diode (LED) is provided. The spherical vertical micro LED is arranged in a loading well of a backplane to form a micro-LED array. The spherical vertical micro LED includes a first semiconductor layer, a second semiconductor layer, a light-emitting layer, a first electrode, a second electrode, and an insulating layer. The light-emitting layer is disposed between the first semiconductor layer and the second semiconductor layer. The first electrode is covered on at least part of a surface of the first semiconductor layer. The second electrode is covered on at least part of a surface of the second semiconductor layer. The insulating layer is covered on an outside surface of the light-emitting layer, or covered on the outside surface of the light-emitting layer as well as part of the surface of the first semiconductor layer and part of the surface of the second semiconductor layer. The first semiconductor layer, the second semiconductor layer, and the light-emitting layer form a sphere structure. The first electrode, the second electrode, and the insulating layer form a spherical structure.

A method for manufacturing a spherical vertical micro LED is provided. The method includes the following. An epitaxial layer is deposited on a substrate, where the epitaxial layer includes a second semiconductor layer, a light-emitting layer, and a first semiconductor layer stacked on the substrate sequentially in a direction approaching the substrate. The second semiconductor layer and part of the light-emitting layer are etched to obtain a first chip hemisphere. A first insulating layer is deposited on the first chip hemisphere. The first insulating layer is etched to expose the second semiconductor layer. A second electrode is coated on the second semiconductor layer exposed. The first chip hemisphere is turned over to be covered on a soft layer of a bonding substrate. The substrate is removed to expose the first semiconductor layer. The first semiconductor layer and part of the light-emitting layer are etched to obtain a second chip hemisphere. A second insulating layer is deposited on the second chip hemisphere. The second insulating layer is etched to expose the first semiconductor layer. A first electrode is coated on the first semiconductor layer exposed. The soft layer and the bonding substrate are removed to obtain the spherical vertical micro LED.

A micro LED display panel is provided. The micro LED display panel includes a backplane, multiple spherical vertical micro LEDs, a transparent connection circuit, and multiple magnetic metal gaskets. The backplane defines multiple loading wells, where the multiple loading wells form a loading-well array. Each of the multiple spherical vertical micro LEDs is the above spherical vertical micro LED. The multiple spherical vertical micro LEDs are arranged in the multiple loading wells in one-to-one correspondence and form a micro-LED array. The transparent connection circuit is coupled with first electrodes of the spherical vertical micro LEDs and a first port of the backplane to realize electrical connections between the first electrodes and the outside. The multiple magnetic metal gaskets are arranged in the multiple loading wells in one-to-one correspondence, where the multiple magnetic metal gaskets are coupled with second electrodes of the spherical vertical micro LEDs and a second port of the backplane to realize electrical connections between the second electrodes and the outside.

A transfer method for a micro LED display panel is provided. The method includes the following. Multiple spherical vertical micro LEDs are placed in a suspension, where each of the spherical vertical micro LEDs is the above spherical vertical micro LED. A backplane is placed in the suspension to make the spherical vertical micro LEDs float above the backplane. The backplane defines multiple loading wells which form a loading-well array, and each of the multiple loading wells is provided with a magnetic metal gasket. Materials of the second electrode include a conductive magnetic material, and the second electrode has a magnetism opposite to that of the magnetic metal gasket in the loading well. A magnetism between the second electrode and the magnetic metal gasket allows the spherical vertical micro LED to be adsorbed in the loading well to form a micro-LED array, to realize transfer of the spherical vertical micro LEDs.

### BRIEF DESCRIPTION OF THE DRAWINGS

FIG. 1 is a schematic structural diagram illustrating a spherical vertical micro light-emitting diode (LED) according to implementations.

FIG. 2 is a schematic structural diagram illustrating a substrate and an epitaxial layer involved in a method for manufacturing a spherical vertical micro LED according to implementations.

FIG. 3 is a schematic structural diagram illustrating an operation of etching to obtain a first hemisphere of a method for manufacturing a spherical vertical micro LED according to implementations.

FIG. 4 is a schematic structural diagram illustrating an operation of depositing an insulating layer on a first hemisphere of a method for manufacturing a spherical vertical micro LED according to implementations.

FIG. 5 is a schematic structural diagram illustrating an operation of etching an insulating layer for a first time of a method for manufacturing a spherical vertical micro LED according to implementations.

FIG. 6 is a schematic structural diagram illustrating an operation of coating a second electrode of a method for manufacturing a spherical vertical micro LED according to implementations.

FIG. 7 is a schematic structural diagram illustrating an operation of loading a bonding substrate of a method for manufacturing a spherical vertical micro LED according to implementations.

FIG. 8 is a schematic structural diagram illustrating an operation of removing a substrate of a method for manufacturing a spherical vertical micro LED according to implementations.

FIG. 9 is a schematic structural diagram illustrating an operation of etching to obtain a second hemisphere of a method for manufacturing a spherical vertical micro LED according to implementations.

FIG. 10 is a schematic structural diagram illustrating an operation of depositing an insulating layer on a second hemisphere of a method for manufacturing a spherical vertical micro LED according to implementations.

FIG. 11 is a schematic structural diagram illustrating an operation of etching an insulating layer for a second time of a method for manufacturing a spherical vertical micro LED according to implementations.

FIG. 12 is a schematic structural diagram illustrating an operation of coating a first electrode of a method for manufacturing a spherical vertical micro LED according to implementations.

FIG. 13 is a schematic diagram of a transfer method for a micro LED display panel according to implementations.

FIG. 14 illustrates a patterned shape of a spherical vertical micro LED according to a first implementation.

FIG. 15 illustrates a patterned shape of a spherical vertical micro LED according to a second implementation.

FIG. 16 illustrates a patterned shape of a spherical vertical micro LED according to a third implementation.

Components represented by reference numbers illustrated in the above figures include: first semiconductor layer 1, second semiconductor layer 2, light-emitting layer 3, first electrode 4, insulating layer 5, second electrode 6, patterned shape 7, backplane 101, substrate 102, bonding substrate 103, soft layer 104, first chip hemisphere 105, and second chip hemisphere 106.

### DETAILED DESCRIPTION

In order to make objectives, technical solutions, and advantages of the disclosure more clear and definite, the disclosure will be described in detail below with reference to accompanying drawings and illustrative implementations. It should be understood that, the implementations described below are merely used to explain the disclosure, and should not be construed as limiting the disclosure.

It should be understood that in the description of the disclosure, an orientation or a positional relationship indicated by the terms “center”, “upper”, “lower”, “front”, “rear”, “left”, “right”, etc. are based on an orientation or a positional relationship illustrated in the accompanying drawings, which is only for simplifying and facilitating description of the disclosure, rather than indicating or implying that a device or a component must have a specific orientation, be constructed and operated in a specific orientation, and therefore should not be understood as a limitation to the disclosure. In addition, the terms “first”, “second”, and the like are only used for descriptive purposes, which should not be understood as indicating or implying relative importance.

It should also be understood that in the description of the disclosure, unless the context clearly indicates otherwise, the terms “mounted”, “coupled”, and “connected” should be broadly understood. For example, the terms may refer to a fixed connection, a removable connection, or an integrated connection; or, may refer to a mechanical connection or an electrical connection; or, may refer to a direct connection, an indirect connection via an intermediary, or an internal communication or interaction of two components. When a component is “fixed to” or “disposed on” another component, the component may be directly on another component or may be on another component via an intermediate component. When a component is “connected to” to another component, the component may be directly connected to another component or may be connected to another component via an intermediate component. For those skilled in the art, the meanings of the above terms referred to in the disclosure may be understood based on specific situations.

Mass transfer refers to a process of transferring a large number of micro light-emitting diodes (LEDs) of small size to a substrate to form a micro-LED array to constitute an LED display panel. The existing LED chip generally has a cuboid structure or a cylindrical structure. During transferring, the micro LED is often stuck outside the loading well of the substrate due to limitation of its shape. As a result, the micro LED cannot be accurately aligned with the loading well, which in turn results in the micro LED not being embedded in the loading well, thus limiting a transfer yield and a production efficiency to a large extent. In view of the above deficiencies, a spherical vertical micro LED and a manufacturing method thereof, a display panel, and a transfer method for the display panel are provided, which can simplify a mass transfer process and allow a transfer efficiency of technical solutions of the disclosure far beyond that of traditional solutions.

Hereinafter, technical solutions of the disclosure will be described in detail with reference to FIG. 1 to FIG. 13.

A spherical vertical micro LED is provided. The spherical vertical micro LED is arranged in a loading well of a backplane to form a micro-LED array. The spherical vertical micro LED includes a first semiconductor layer, a second semiconductor layer, a light-emitting layer, a first electrode, a second electrode, and an insulating layer. The light-emitting layer is disposed between the first semiconductor layer and the second semiconductor layer. The first electrode is covered on at least part of a surface of the first semiconductor layer. The second electrode is covered on at least part of a surface of the second semiconductor layer. The insulating layer is covered on an outside surface of the light-emitting layer, or covered on the outside surface of the light-emitting layer as well as part of the surface of the first semiconductor layer and part of the surface of the second semiconductor layer. The first semiconductor layer, the second semiconductor layer, and the light-emitting layer form a sphere structure. The first electrode, the second electrode, and the insulating layer form a spherical structure.

Compared to the related art, in the disclosure, the first semiconductor layer, the second semiconductor layer, and the light-emitting layer form a sphere structure, and the first electrode, the second electrode, and the insulating layer form a spherical structure which is covered on an outside surface of the sphere structure, which can avoid a case where the micro LED is stuck outside the loading well, and facilitate accurate alignment with the loading well during transferring, thereby effectively improving a transfer yield and a production efficiency.

In some implementations, materials of the second electrode include a conductive magnetic material. The second electrode has a magnetism opposite to that of a magnetic metal gasket in the loading well.

According to these implementations, the materials of the second electrode include a conductive magnetic material, and the second electrode has a magnetism opposite to that of a magnetic metal gasket in the loading well. As such, the spherical vertical micro LED can be adsorbed in the loading well under action of a magnetism during transferring, and an effective contact between the second electrode and the magnetic metal gasket can be ensured.

In some implementations, the conductive magnetic material of the second electrode forms a patterned shape. In some implementations, the patterned shape is a triangle, a rectangle, a circle, a cross, or a ring.

According to these implementations, it is beneficial to fixing different spherical vertical micro LEDs in their respective positions.

In some implementations, a surface of the second electrode is provided with an alignment protrusion portion for alignment. Accordingly, the loading well is provided with an alignment recess portion. The alignment protrusion portion has a shape matched with that of the alignment recess portion.

According to these implementations, the alignment protrusion portion on the second electrode is embedded in the alignment recess portion of the loading well. As such, the spherical vertical micro LED can be disposed in the loading well accurately and firmly.

In some implementations, the alignment protrusion portion has a cross section in a shape of a triangle, a rectangle, a circle, a cross, or a ring. Accordingly, the alignment recess portion has a cross section in a shape of a triangle, a rectangle, a circle, a cross, or a ring.

According to these implementations, by providing alignment protrusion portions and alignment recess portion of different shapes, spherical vertical micro LEDs with alignment protrusion portions of different shapes can be embedded in their respective alignment recess portions.

In some implementations, the spherical vertical micro LED includes an R-type LED, a G-type LED, and a B-type LED. Spherical structures of the R-type LED, the G-type LED, and the B-type LED are in different diameters.

According to these implementations, by providing the R-type LED, the G-type LED, and the B-type LED having spherical structures of different diameters, automatic arrangement during transferring can be realized, thereby further improving a transfer efficiency.

In some implementations, the first electrode is made of a transparent material. The second electrode is made of a conductive material with high reflectivity, such as, silver.

According to these implementations, the second electrode is made of a conductive material with high reflectivity, which can improve a light extraction efficiency. The first electrode is made of a transparent material, which allows lights to be emitted smoothly.

In some implementations, the first semiconductor layer is made of n-GaN, the second semiconductor layer is made of p-GaN, the light-emitting layer is made of InGaN or InN, the first electrode is made of ITO, and the insulating layer is made of silicon dioxide.

A method for manufacturing a spherical vertical micro LED is provided. The method includes the following. An epitaxial layer is deposited on a substrate, where the epitaxial layer includes a second semiconductor layer, a light-emitting layer, and a first semiconductor layer stacked on the substrate sequentially in a direction approaching the substrate. The second semiconductor layer and part of the light-emitting layer are etched to obtain a first chip hemisphere. A first insulating layer is deposited on the first chip hemisphere. The first insulating layer is etched to expose the second semiconductor layer. A second electrode is coated on the second semiconductor layer exposed. The first chip hemisphere is turned over to be covered on a soft layer of a bonding substrate. The substrate is removed to expose the first semiconductor layer. The first semiconductor layer and part of the light-emitting layer are etched to obtain a second chip hemisphere. A second insulating layer is deposited on the second chip hemisphere. The second insulating layer is etched to expose the first semiconductor layer. A first electrode is coated on the first semiconductor layer exposed. The soft layer and the bonding substrate are removed to obtain the spherical vertical micro LED.

Compared to the related art, in the disclosure, two hemispherical structures are formed sequentially by means of deposition and etching on the basis of the first semiconductor layer, the second semiconductor layer, and the light-emitting layer, and the first electrode, the insulating layer, and the second electrode are obtained by means of electroplating, so as to form the spherical vertical micro LED, which can avoid a case where the micro LED is stuck outside the loading well, and facilitate accurate alignment with the loading well during transferring, thereby effectively improving a transfer yield and a production efficiency.

A micro LED display panel is provided. The micro LED display panel includes a backplane, multiple spherical vertical micro LEDs, a transparent connection circuit, and multiple magnetic metal gaskets. The backplane defines multiple loading wells, where the multiple loading wells form a loading-well array. Each of the multiple spherical vertical micro LEDs is the above spherical vertical micro LED. The multiple spherical vertical micro LEDs are arranged in the multiple loading wells in one-to-one correspondence and form a micro-LED array. The transparent connection circuit is coupled with first electrodes of the spherical vertical micro LEDs and a first port of the backplane to realize electrical connections between the first electrodes and the outside. The multiple magnetic metal gaskets are arranged in the multiple loading wells in one-to-one correspondence, where the multiple magnetic metal gaskets are coupled with second electrodes of the spherical vertical micro LEDs and a second port of the backplane to realize electrical connections between the second electrodes and the outside.

Compared to the related art, in the disclosure, the multiple spherical vertical micro LEDs are respectively embedded in the multiple loading wells of the backplane, to form a display panel. As such, in addition to achieving a more ideal photoelectric efficiency, brightness, and contrast as well as lower power consumption, it is possible to improve a transfer yield and a production efficiency.

A transfer method for a micro LED display panel is provided. The method includes the following. Multiple spherical vertical micro LEDs are placed in a suspension, where each of the spherical vertical micro LEDs is the above spherical vertical micro LED. A backplane is placed in the suspension to make the spherical vertical micro LEDs float above the backplane. The backplane defines multiple loading wells which form a loading-well array, and each of the multiple loading wells is provided with a magnetic metal gasket. Materials of the second electrode include a conductive magnetic material, and the second electrode has a magnetism opposite to that of the magnetic metal gasket in the loading well. A magnetism between the second electrode and the magnetic metal gasket allows the spherical vertical micro LED to be adsorbed in the loading well to form a micro-LED array, to realize transfer of the spherical vertical micro LEDs.

Compared to the related art, in the disclosure, the magnetic metal gasket is arranged in the loading well of the backplane, the materials of the second electrode include a conductive magnetic material, and the second electrode has a magnetism opposite to that of the magnetic metal gasket. As such, the spherical vertical micro LED can be adsorbed in the loading well, which is conducive to accurate alignment with the loading well during transferring, thereby effectively improving a transfer yield and a production efficiency.

A spherical vertical micro LED is provided. The spherical vertical micro LED is disposed in a loading well of a backplane 101 to form a micro-LED array. As illustrated in FIG. 1, the spherical vertical micro LED includes a first semiconductor layer 1, a second semiconductor layer 2, a light-emitting layer 3, a first electrode 4, an insulating layer 5, and a second electrode 6. The working principle of the spherical vertical micro LED is as follows. The insulating layer 5 separates the first electrode 4 and the second electrode 6. The first semiconductor layer 1 is electrically connected to the outside via the first electrode 4, and the second semiconductor layer 2 is electrically connected to the outside via the second electrode 6. Electrons and holes are injected into the first semiconductor layer 1 from the first electrode 4, and are injected into the second semiconductor layer 2 from the second electrode 6. Then electrons and holes are recombined in the light-emitting layer 3 between the first semiconductor layer 1 and the second semiconductor layer 2, to release energy in a form of photons, thereby realizing lighting.

In the disclosure, the first semiconductor layer 1, the second semiconductor layer 2, and the light-emitting layer 3 form a sphere structure. The first electrode 4, the insulating layer 5, and the second electrode 6 form a spherical structure. The spherical structure (i.e., a hollow sphere) formed by the first electrode 4, the insulating layer 5, and the second electrode 6 wraps the sphere structure (i.e., a solid sphere) formed by the first semiconductor layer 1, the second semiconductor layer 2, and the light-emitting layer 3, to form the spherical vertical micro LED as a whole. Specifically, the light-emitting layer 3 is disposed between the first semiconductor layer 1 and the second semiconductor layer 2. The first electrode 4 is covered on at least part of a surface of the first semiconductor layer 1. The second electrode 6 is covered on at least part of a surface of the second semiconductor layer 2. The insulating layer 5 is covered on an outside surface of the light-emitting layer 3, or covered on the outside surface of the light-emitting layer 3 as well as part of the surface of the first semiconductor layer 1 and part of the surface of the second semiconductor layer 2.

The insulating layer 5 is used to separate the first semiconductor layer 1 and the second semiconductor layer 2. In one implementation, when manufacturing the spherical vertical micro LED, the first electrode 4 is covered on the entire outside surface of the first semiconductor layer 1, the second electrode 6 is covered on the entire outside surface of the second semiconductor layer 2, and the insulating layer 5 is covered only on an outside surface of the light-emitting layer 3. In another implementation, as illustrated in FIG. 1, the first electrode 4 is covered on part of the outside surface of the first semiconductor layer 1, the second electrode 6 is covered on part of the outside surface of the second semiconductor layer 2, and the insulating layer 5 is covered on part of the outside surface of the first semiconductor layer 1 and part of the outside surface of the second semiconductor layer 2 in addition to the outside surface of the light-emitting layer 3. In a word, the insulating layer is used to separate the first electrode and the second electrode. Therefore, in terms of structure distribution, the insulating layer may be covered only on the outside surface of the light-emitting layer. In addition, the insulating layer covered on the outside surface of the light-emitting layer may be extended to be covered on part of the outside surface of the first semiconductor layer 1 and part of the outside surface of the second semiconductor layer 2.

By adopting the above technical solutions, the first semiconductor layer 1, the second semiconductor layer 2, and the light-emitting layer 3 can form a sphere structure, and the first electrode 4, the insulating layer 5, and the second electrode 6 can form a spherical structure which is covered on an outside surface of the sphere structure. In this way, spherical vertical micro LEDs formed by the sphere structure and the spherical structure are obtained to match multiple hemispherical loading wells defined on the backplane 101, which can effectively avoid a case where the micro LED is stuck outside the loading well, so that the spherical vertical micro LEDs can be transferred to the backplane 101 easily, quickly, and efficiently. As such, accurate alignment can be achieved, thereby effectively improving a transfer yield and a production efficiency.

Furthermore, in the disclosure, a magnetism is adopted to assist in improving a transfer efficiency of the spherical vertical micro LEDs. In some implementations, materials of the second electrode 6 include a conductive magnetic material. The second electrode 6 has a magnetism opposite to that of a magnetic metal gasket in a loading well.

In the disclosure, the materials of the second electrode 6 include a conductive magnetic material, and the second electrode 6 has a magnetism opposite to that of the magnetic metal gasket in the loading well. Accordingly, there is a magnetism between the magnetic metal gasket and the second electrode 6. The magnetic metal gasket is fixed in the loading well. The second electrode 6 of the spherical vertical micro LED is absorbed toward the magnetic metal gasket under action of the magnetism, so that the spherical vertical micro LED is adsorbed in the loading well. In addition, the magnetic metal gasket also has an electrical connection function. Based on the above technical solutions, it is possible to not only improve the transfer efficiency of the spherical vertical micro LEDs, but also ensure an effective contact between the second electrode 6 and the magnetic metal gasket.

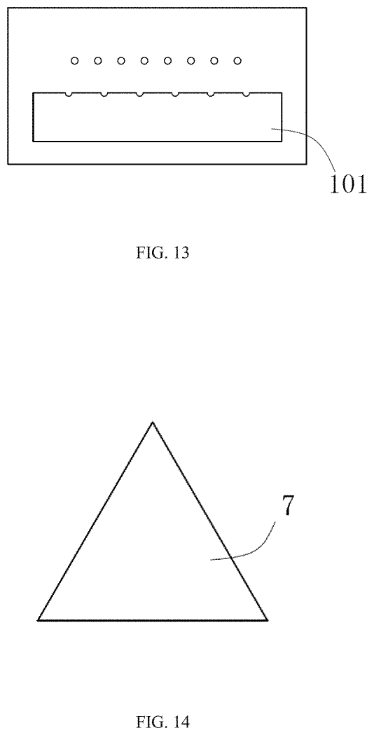

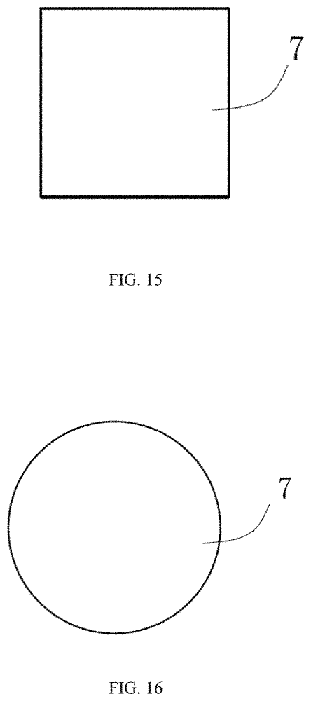

In some implementations, the conductive magnetic material of the second electrode forms a patterned shape 7, and the patterned shape 7 of the conductive magnetic material may be a triangle, a rectangle, a circle, a cross, or a ring (see FIG. 14, FIG. 15, and FIG. 16). Accordingly, the magnetic metal gasket is set to have a patterned shape 7, and the patterned shape 7 of the magnetic metal gasket may also be a triangle, a rectangle, a circle, a cross, or a ring. In a word, part of the second electrode is magnetic while the other part is not. In terms of appearance, magnetic part of a spherical structure may be in various shapes, such as, a triangle, a square, a circle, etc. The magnetic part in a patterned shape can also facilitate alignment. The patterned shape herein refers to a projected shape formed on a surface of the spherical structure.

By adopting above technical solutions, different spherical vertical micro LEDs can be fixed in their respective positions. As an example, the patterned shape of the magnetic metal gasket includes a triangle and a circle, and accordingly, spherical vertical micro LEDs with a conductive magnetic material of a triangle and a conductive magnetic material of a circle are produced. When transferring, spherical vertical micro LEDs with a conductive magnetic material of a triangle are matched first. Accordingly, most of the spherical vertical micro LEDs with a conductive magnetic material of a triangle can be absorbed by triangular magnetic metal gaskets, so as to be fixed. Even if a small amount of the spherical vertical micro LEDs with a conductive magnetic material of a triangle are absorbed by circular magnetic metal gaskets, since the spherical vertical micro LED with a conductive magnetic material of a triangle does not match the circular magnetic metal gasket in shape, a magnetism generated between the spherical vertical micro LED and the circular magnetic metal gasket is relatively weak. In this case, adsorbed IEDs that do not match in shape can fall off by gently shaking. Similarly, spherical vertical micro LEDs with a conductive magnetic material of a circle are then matched. Accordingly, the spherical vertical micro LEDs with a conductive magnetic material of a circle can be absorbed by circular magnetic metal gaskets, so as to be fixed. Thus, a convenient transfer can be realized.

In some implementations, a surface of the second electrode 6 is provided with an alignment protrusion portion for alignment. Accordingly, the loading well is provided with an alignment recess portion, that is, the alignment recess portion is further formed in the loading well by means of depression. The alignment protrusion portion has a shape matched with that of the alignment recess portion. In some implementations, the alignment protrusion portion has a cross section in a shape of a triangle, a rectangle, a circle, a cross, or a ring. Accordingly, the alignment recess portion has a cross section in a shape of a triangle, a rectangle, a circle, a cross, or a ring.

As we all know, the three optical primary colors include red, green, and blue. All colors needed for display can be formed by mixing the three optical primary colors, so that a display effect on a display screen can be realized. Based on this, the spherical vertical micro LED of the disclosure includes an R-type LED, a G-type LED, and a B-type LED, where the R-type LED is configured to emit red lights, the G-type LED is configured to emit green lights, and the B-type LED is configured to emit blue lights. In a process of manufacturing a micro LED display panel, in order to realize a display function, it is necessary to arrange R-type LEDs, G-type LEDs, and B-type LEDs in a specific pattern. In the related art, it is very difficult to accurately arrange R-type LEDs, G-type LEDs, and B-type LEDs in their respective positions due to the small size and the large number of these LED chips. However, in the disclosure, the above problems can be solved by providing an alignment protrusion portion and an alignment recess portion of a specific shape and a specific outer contour.

Alignment protrusion portions of the R-type LED, the G-type LED, and the B-type LED are in different shapes. For example, the alignment protrusion portion of the R-type LED has a cross section in a shape of a rectangle, the alignment protrusion portion of the G-type LED has a cross section in a shape of a circle, and the alignment protrusion portion of the B-type LED has a cross section in a shape of a triangle. Accordingly, according to a predetermined pattern, part of loading wells are set to have a cross section in a shape of a rectangle, part of the loading wells are set to have a cross section in a shape of a circle, and the other part of the loading wells are set to have a cross section in a shape of a triangle. When transferring, a magnetic metal gasket in each loading well can generate a magnetism with a second electrode 6 of the spherical vertical micro LED. However, in the case that the shape of the alignment protrusion portion does not match that of the alignment recess portion, an adsorption force between the alignment protrusion portion and the alignment recess portion is relatively small. To this end, wrongly matched LEDs can be separated from a backplane 101 by vibration, so as to be re-adsorbed. The foregoing operations are repeated until all matching is correct. As such, a transfer yield and a production efficiency can be improved.

Generally, an LED chip includes a front-mounted LED chip, an LED flip chip, and a vertical LED chip. The micro LED of the disclosure belongs to a vertical chip. In terms of structure, a light-emitting layer of the vertical chip is disposed between a first semiconductor layer of the vertical chip and a second semiconductor layer of the vertical chip. When working, the light-emitting layer is configured to emit photons in all directions. When photons are emitted toward the first semiconductor layer, the emitted photons are emitted to the outside via the first semiconductor layer and a first electrode of the vertical chip directly. When photons are emitted toward the second semiconductor layer, after passing through the second semiconductor layer and a second electrode of the vertical chip, the emitted photons are reflected to change an emission direction and then emitted to the outside via the first semiconductor layer and the first electrode. To this end, the first electrode is made of a transparent material, and the second electrode is made of a conductive material with high reflectivity. In the disclosure, the second electrode is made of a high-reflectivity conductive material, which can improve light extraction efficiency. In addition, the first electrode is made of transparent material, which makes it possible for lights to be emitted.

In some implementations, the first semiconductor layer 1 is made of n-GaN, the second semiconductor layer 2 is made of p-GaN, the light-emitting layer 3 is made of InGaN or InN, the first electrode 4 is made of ITO, and the insulating layer 5 is made of silicon dioxide. In other implementations, the micro LED is manufactured as follows. Materials of the first semiconductor layer include one of N-type gallium arsenide, N-type copper phosphide, and other materials. Materials of the second semiconductor layer include one of P-type gallium arsenide, P-type copper phosphide, and other materials. Materials of the light-emitting layer include one or more of indium gallium aluminum nitride, gallium arsenide, aluminum gallium arsenide, indium gallium phosphide, indium arsenide phosphide, and indium gallium arsenide. Materials of the first electrode include one or any combination of titanium, aluminum, nickel, and their alloys. It should be noted that, the above are merely illustrative implementations, and the materials of the first semiconductor layer 1, the second semiconductor layer 2, the light-emitting layer 3, the first electrode 4, and the insulating layer 5 are not limited in the disclosure. All other materials that achieve a same function based on a same principle are shall fall within the protection scope of the disclosure, and the materials involved are not exhaustively listed herein.

In the disclosure, a method for manufacturing a spherical vertical micro LED is further provided. The method includes the following. An epitaxial layer is deposited on a substrate 102, where the epitaxial layer includes a second semiconductor layer 2, a light-emitting layer 3, and a first semiconductor layer 1 stacked on the substrate 102 sequentially in a direction approaching the substrate 102. The second semiconductor layer 2 and part of the light-emitting layer 3 are etched to obtain a first chip hemisphere 105. A first insulating layer is deposited on the first chip hemisphere 105, so that the first insulating layer is covered on the first chip hemisphere 105. The first insulating layer is etched to expose the second semiconductor layer 2. A second electrode 6 is coated on the second semiconductor layer 2 exposed. The first chip hemisphere 105 is turned over to be covered on a soft layer 104 of a bonding substrate 103. The substrate 102 is removed to expose the first semiconductor layer 1. The first semiconductor layer 1 and part of the light-emitting layer 3 are etched to obtain a second chip hemisphere 106. A second insulating layer is deposited on the second chip hemisphere 106, so that the second insulating layer is covered on the second chip hemisphere 106. The second insulating layer is etched to expose the first semiconductor layer 1. A first electrode 4 is coated on the first semiconductor layer 1 exposed. The bonding substrate 103 and the soft layer 104 are removed to obtain the spherical vertical micro LED.

In some implementations, materials of the second electrode 6 include a conductive magnetic material.

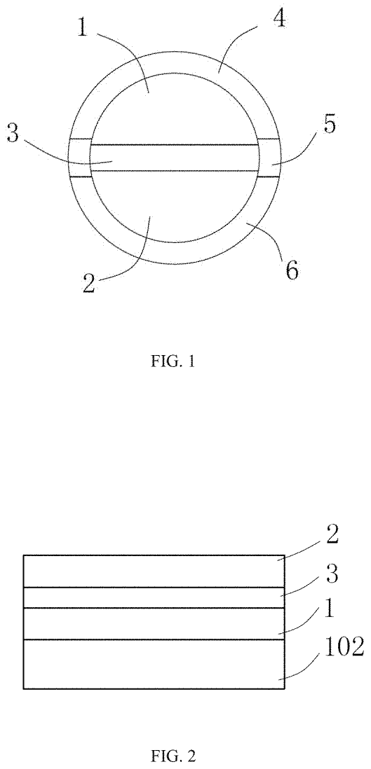

Hereinafter, the above method will be described according to a production process flow with reference to FIG. 2 to FIG. 12.

As illustrated in FIG. 2, an epitaxial layer is first formed on a substrate 102, where the epitaxial layer includes a first semiconductor layer 1, a second semiconductor layer 2, and a light-emitting layer 3. The light-emitting layer 3 is disposed between the first semiconductor layer 1 and the second semiconductor layer 2.

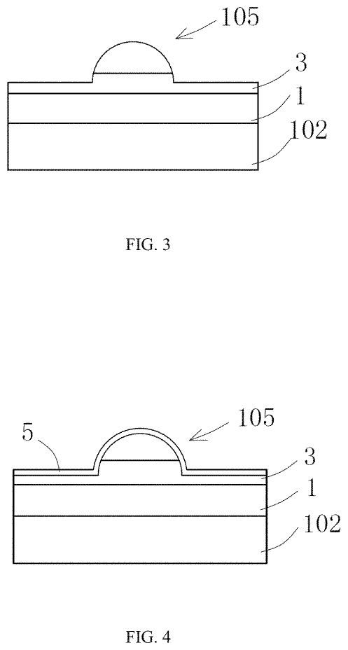

As illustrated in FIG. 3, the epitaxial layer is etched through a dry etching process to obtain a first chip hemisphere 105. As an example, part of the second semiconductor layer and the light-emitting layer is etched away to leave a hemispherical structure (i.e., the first chip hemisphere 105).

As illustrated in FIG. 4, a first insulating layer is obtained by depositing on the second semiconductor layer 2 and the light-emitting layer 3, so that the first insulating layer is covered on the second semiconductor layer and the light-emitting layer.

As illustrated in FIG. 5, the first insulating layer covered on upper part of the first chip hemisphere 105 is etched away to expose the second semiconductor layer of the first chip hemisphere 105, and small part of the first insulating layer corresponding to the juncture of the second semiconductor layer and the light-emitting layer is remained. The remained first insulating layer is used for insulation.

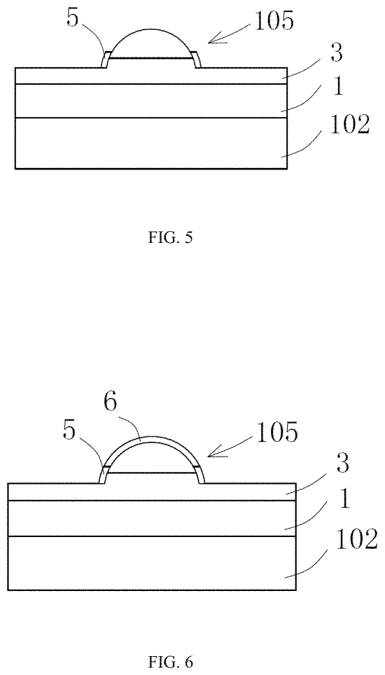

As illustrated in FIG. 6, after the second semiconductor layer of the first chip hemisphere 105 is exposed, a second electrode 6 is further coated on the exposed second semiconductor layer. In some implementations, materials of the second electrode 6 include a conductive magnetic material, to prepare for the mass transfer. The second electrode 6 has a magnetism opposite to that of a magnetic metal gasket in a loading well.

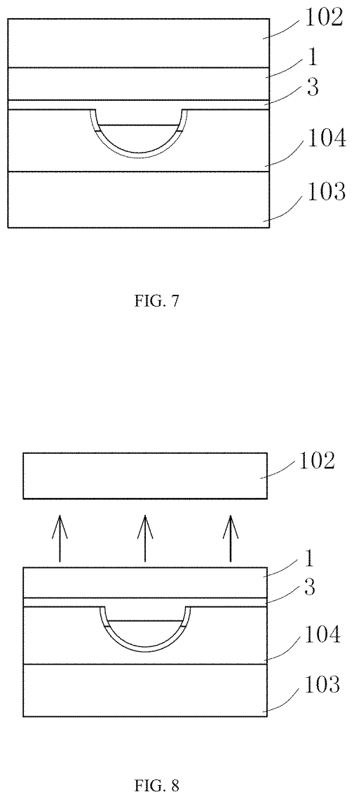

As illustrated in FIG. 7, after the second electrode 6 is coated, the first chip hemisphere 105 is turned over to be covered on a bonding substrate 103. In some implementations, the bonding substrate 103 is provided with a soft layer 104. Accordingly, the first chip hemisphere 105 is turned over to be covered on the bonding substrate 103 as follows. The first chip hemisphere 105 is turned over to be covered on the soft layer 104 of the bonding substrate 103. After completing this operation, an orientation of the first chip hemisphere 105 is changed to downward from upward.

As illustrated in FIG. 8, the substrate 102 currently disposed at the uppermost layer is removed to expose the first semiconductor layer 1. In this case, a semi-finished product of the spherical vertical micro LED includes the first semiconductor layer 1, the light-emitting layer 3, and the second semiconductor layer 2 stacked sequentially in a direction approaching the bonding substrate, where the second semiconductor layer 2 is covered with the second electrode 6.

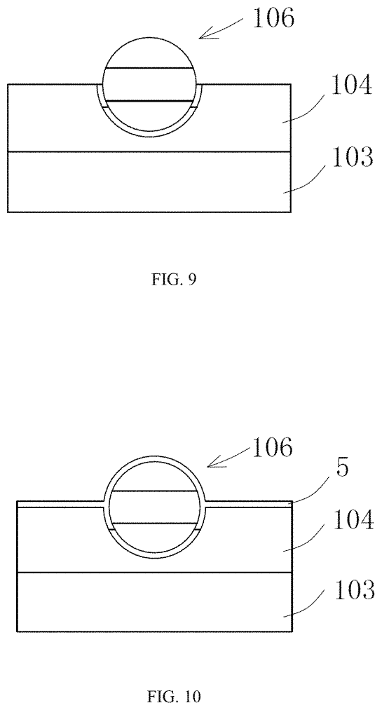

As illustrated in FIG. 9, after the substrate 102 is removed to expose the first semiconductor layer 1, a second chip hemisphere 106 is obtained through a dry etching process. As an example, part of the first semiconductor layer 1 and the light-emitting layer 3 is etched away to leave a hemispherical structure (i.e., the second chip hemisphere 106). In this case, the second chip hemisphere 106 and the first chip hemisphere 105 form a complete sphere structure. The complete sphere structure refers to a sphere structure formed by the first semiconductor layer 1, the second semiconductor layer 2, and the light-emitting layer 3.

As illustrated in FIG. 10, a second insulating layer is obtained by depositing on the first semiconductor layer 1 and the light-emitting layer 3, so that the second insulating layer is covered on the first semiconductor layer and the light-emitting layer.

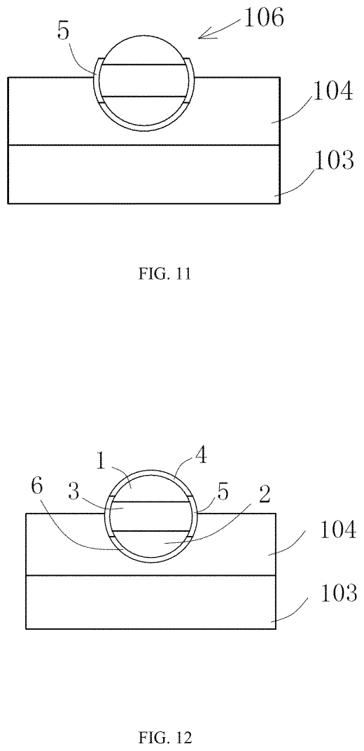

As illustrated in FIG. 11, the second insulating layer covered on upper part of the second chip hemisphere 106 is etched away to expose the first semiconductor layer of the second chip hemisphere 106, and small part of the second insulating layer corresponding to the juncture of the first semiconductor layer and the light-emitting layer is remained. The remained second insulating layer is used for insulation. The remained first insulating layer and the remained second insulating layer are combined to form a complete insulating layer 5, where the insulating layer 5 is used to isolate the first semiconductor layer and the second semiconductor layer.

As illustrated in FIG. 12, after the first semiconductor layer 1 of the second chip hemisphere 106 is exposed, a first electrode 4 is further coated on the exposed first semiconductor layer 1. In some implementations, the first electrode 4 is made of a transparent material to facilitate light emission. At this time, the first electrode 4, the insulating layer 5, and the second electrode 6 form a spherical structure, and the spherical structure wraps a sphere structure formed by the first semiconductor layer 1, the second semiconductor layer 2, and the light-emitting layer 3, to obtain the spherical vertical micro LED.

In sum, two hemispherical structures are formed sequentially by means of deposition and etching on the basis of the first semiconductor layer 1, the second semiconductor layer 2, and the light-emitting layer 3. The first electrode 4, the insulating layer 5, and the second electrode 6 are obtained by means of electroplating. In this way, the spherical vertical micro LED is formed, which can avoid a case where the micro LED is stuck outside the loading well, and facilitate accurate alignment with the loading well during transferring, thereby effectively improving a transfer yield and a production efficiency.

In the disclosure, a micro LED display panel is further provided. The micro LED display panel mainly includes a backplane 101. The foregoing spherical vertical micro LED is mounted on the backplane 101, to form the micro LED display panel.

Specifically, the backplane 101 defines multiple loading wells which have a size matched with that of the spherical vertical micro LED. Each of the multiple loading wells is provided with a magnetic metal gasket matched with a second electrode 6 of the spherical vertical micro LED. A micro-LED array is formed after multiple spherical vertical micro LEDs are fixed in the loading wells of the backplane 101 in one-to-one correspondence. A transparent connection circuit is coated on a first electrode 4 of the spherical vertical micro LED. The transparent connection circuit is coupled with the first electrode 4 and a first port of the backplane 101 to realize an electrical connection between the first electrode 4 and the outside. Also, a second electrode 6 of the spherical vertical micro LED is coupled with a second port of the backplane 101 via a magnetic metal gasket, to realize an electrical connection between the second electrode 6 and the outside.

In some implementations, the second electrode 6 has a magnetism opposite to that of the magnetic metal gasket in the loading well. As such, it is convenient for the spherical vertical micro LED to be adsorbed to the loading well under action of a magnetism during transferring. Moreover, an effective contact between the second electrode 6 and the magnetic metal gasket can be ensured.

In some implementations, a surface of the second electrode 6 is provided with an alignment protrusion portion for alignment. Accordingly, the loading well is provided with an alignment recess portion. The alignment protrusion portion has a shape matched with that of the alignment recess portion. In some implementations, the alignment protrusion portion has a cross section in a shape of a triangle, a rectangle, a circle, a cross, or a ring. Accordingly, the alignment recess portion has a cross section in a shape of a triangle, a rectangle, a circle, a cross, or a ring.

In some implementations, the spherical vertical micro LED includes an R-type LED, a G-type LED, and a B-type LED. Spherical structures of the R-type LED, the G-type LED, and the B-type LED are in different diameters.

In the disclosure, a transfer method for a micro LED display panel is further provided. The method includes the following. As illustrated in FIG. 13, multiple spherical vertical micro LEDs are placed in a suspension, where each of the spherical vertical micro LEDs is the foregoing spherical vertical micro LED. A backplane 101 is placed in the suspension to make the spherical vertical micro LEDs float above the backplane 101, where the backplane 101 defines multiple loading wells which form a loading-well array, and each of the multiple loading wells is provided with a magnetic metal gasket; where materials of the second electrode 6 include a conductive magnetic material, and the second electrode 6 has a magnetism opposite to that of the magnetic metal gasket in the loading well. A magnetism between the second electrode 6 and the magnetic metal gasket allows the spherical vertical micro LED to be adsorbed in the loading well to form a micro-LED array, to realize transfer of the spherical vertical micro LEDs.

It should be noted that, the above is only a process of transferring spherical vertical micro LEDs to the backplane, which however does not include a packaging process. After transferring, packaging is required to form a complete micro LED display panel.

A large number of spherical vertical micro LEDs are placed in a suspension. The backplane 101 is provided with magnetic metal gaskets which have a magnetism opposite to that of the second electrode 6 of the spherical vertical micro LED. The spherical vertical micro LEDs can be adsorbed in the loading wells under action of the magnetism. As such, the spherical vertical micro LEDs can be aligned to the loading wells of the backplane 101 accurately. The function of the magnetic metal gasket can be realized as follows. As an example, the magnetic metal gasket is made of a magnetic material, thus a magnetism can be directly generated by the magnetic metal gasket itself. As another example, according to electromagnetic induction, a magnetism is generated after the magnetic metal gasket is powered on. When the suspension is flowing, the second electrode 6 and the magnetic metal gasket are attracted to each other under action of adsorption of magnetic electrodes.

The spherical vertical micro LED includes an R-type LED, a G-type LED, and a B-type LED. A surface of the second electrode is provided with an alignment protrusion portion for alignment. Accordingly, the loading well is provided with an alignment recess portion. The alignment protrusion portion has a shape matched with that of the alignment recess portion. Alignment protrusion portions of the R-type LED, the G-type LED, and the B-type LED are in different shapes or sizes. For example, the alignment protrusion portion of the R-type LED has a cross section in a shape of a rectangle, the alignment protrusion portion of the G-type LED has a cross section in a shape of a circle, and the alignment protrusion portion of the B-type LED has a cross section in a shape of a triangle. Accordingly, according to a predetermined pattern, part of loading wells are set to have a cross section in a shape of a rectangle, part of the loading wells are set to have a cross section in a shape of a circle, and the other part of the loading wells are set to have a cross section in a shape of a triangle. During transferring, a magnetic metal gasket in each loading well can generate a magnetism with a second electrode of the spherical vertical micro LED. However, when the shape of the alignment protrusion portion does not match that of the alignment recess portion, an adsorption force between the alignment protrusion portion and the alignment recess portion is relatively small. To this end, wrongly matched LEDs can be separated from the backplane by vibration, so as to be re-adsorbed. The foregoing operations are repeated until all matching is correct. As such, a transfer yield and a production efficiency can be improved.

In addition to distinguishing different spherical vertical micro LEDs by providing alignment protrusion portions and alignment recess portions of different shapes, different spherical vertical micro LEDs can also be distinguished by providing the spherical vertical micro LEDs of different sizes. For example, the R-type LED is set to have a sphere structure with a radius of R1, the G-type LED is set to have a sphere structure with a radius of R2, and the B-type LED is set to have a sphere structure with a radius of R3. Accordingly, according to a predetermined pattern, part of loading wells are set to have a cross section in a shape of a circle with a radius of R1, part of the loading wells are set to have a cross section in a shape of a circle with a radius of R2, and the other part of the loading wells are set to have a cross section in a shape of a circle with a radius of R3. In this way, the transfer yield and the production efficiency can also be improved.

In the case that R1>R2>R3, when transferring and assembling with the aid of a suspension, the sizes of the R-type LED, the G-type LED, and the B-type LED are different, and so micro LEDs of three different colors can be transferred in descending order of sizes. For example, R-type LEDs with the largest size are first transferred, and most of the R-type LEDs are stably adsorbed and fixed to loading wells with a radius of R1. Even if a small amount of the R-type LEDs are absorbed to loading wells with a radius of R2 or R3, since the spherical vertical micro LED does not match the loading well in terms of size, a magnetism generated between the spherical vertical micro LED and the loading well is relatively weak. In this case, adsorbed IEDs that does not match in shape can fall off by gently shaking. Similarly, G-type LEDs and B-type LEDs are transferred sequentially, thereby greatly improving a transfer efficiency.

According to the spherical vertical micro-LED and the manufacturing method thereof, the display panel, and the transfer method for the display panel of the disclosure, two hemispherical structures are formed sequentially by means of deposition and etching on the basis of the first semiconductor layer 1, the second semiconductor layer 2, and the light-emitting layer 3. The first electrode 4, the insulating layer 5, and the second electrode 6 are obtained by means of electroplating, so as to form the spherical vertical micro LED, which can avoid a case where the micro LED is stuck outside the loading well, and facilitate accurate alignment with the loading well during transferring, thereby effectively improving a transfer yield and a production efficiency.

While the disclosure has been described in connection with some illustrative implementations, which however are not intended to limit the disclosure. Any modifications, equivalent substitutions, or improvements made by those skilled in the art without departing from the spirits and principles of the disclosure shall all be encompassed within the protection scope of the disclosure.

What is claimed is:

1. A spherical vertical micro light-emitting diode (LED), comprising:
a first semiconductor layer;
a second semiconductor layer;
a light-emitting layer, disposed between the first semiconductor layer and the second semiconductor layer;
a first electrode, covered on at least part of a surface of the first semiconductor layer;
a second electrode, covered on at least part of a surface of the second semiconductor layer; and
an insulating layer, covered on an outside surface of the light-emitting layer or covered on the outside surface of the light-emitting layer as well as part of the surface of the first semiconductor layer and part of the surface of the second semiconductor layer; and
the first semiconductor layer, the second semiconductor layer, and the light-emitting layer forming a sphere structure, and the first electrode, the second electrode, and the insulating layer forming a spherical structure.

2. The spherical vertical micro LED of claim 1, wherein materials of the second electrode comprise a conductive magnetic material, and the second electrode has a magnetism opposite to that of a magnetic metal gasket in a loading well.

3. The spherical vertical micro LED of claim 2, wherein the conductive magnetic material of the second electrode forms a patterned shape.

4. The spherical vertical micro LED of claim 3, wherein the patterned shape is a triangle, a rectangle, a circle, a cross, or a ring.

5. The spherical vertical micro LED of claim 3, wherein the spherical vertical micro LED comprises an R-type LED, a G-type LED, and a B-type LED, and spherical structures of the R-type LED, the G-type LED, and the B-type LED are in different diameters.

6. The spherical vertical micro LED of claim 1, wherein the first electrode is made of a transparent material, and the second electrode is made of a conductive material with high reflectivity.

7. The spherical vertical micro LED of claim 1, wherein the first semiconductor layer is made of n-GaN, the second semiconductor layer is made of p-GaN, the light-emitting layer is made of InGaN or InN, the first electrode is made of ITO, and the insulating layer is made of silicon dioxide.

8. A method for manufacturing a spherical vertical micro light-emitting diode (LED), comprising:
depositing an epitaxial layer on a substrate, the epitaxial layer comprising a second semiconductor layer, a light-emitting layer, and a first semiconductor layer stacked on the substrate sequentially in a direction approaching the substrate;
etching the second semiconductor layer and part of the light-emitting layer to obtain a first chip hemisphere;
depositing a first insulating layer on the first chip hemisphere;
etching the first insulating layer to expose the second semiconductor layer;
coating a second electrode on the second semiconductor layer exposed;
turning the first chip hemisphere over to be covered on a soft layer of a bonding substrate;
removing the substrate to expose the first semiconductor layer;
etching the first semiconductor layer and part of the light-emitting layer to obtain a second chip hemisphere;
depositing a second insulating layer on the second chip hemisphere;
etching the second insulating layer to expose the first semiconductor layer;
coating a first electrode on the first semiconductor layer exposed; and
removing the soft layer and the bonding substrate to obtain the spherical vertical micro LED.

9. The method of claim 8, wherein materials of the second electrode comprise a conductive magnetic material, and the second electrode has a magnetism opposite to that of a magnetic metal gasket in a loading well.

10. The method of claim 9, wherein the conductive magnetic material of the second electrode forms a patterned shape.

11. The method of claim 10, wherein the patterned shape is a triangle, a rectangle, a circle, a cross, or a ring.

12. The method of claim 10, wherein the spherical vertical micro LED comprises an R-type LED, a G-type LED, and a B-type LED, and spherical structures of the R-type LED, the G-type LED, and the B-type LED are in different diameters.

13. The method of claim 8, wherein the first electrode is made of a transparent material, and the second electrode is made of a conductive material with high reflectivity.

14. A micro light-emitting diode (LED) display panel, comprising:
a backplane, defining a plurality of loading wells, wherein the plurality of loading wells form a loading-well array;
a plurality of spherical vertical micro LEDs, wherein
each of the plurality of spherical vertical micro LEDs comprises:
a first semiconductor layer;
a second semiconductor layer;
a light-emitting layer, disposed between the first semiconductor layer and the second semiconductor layer;
a first electrode, covered on at least part of a surface of the first semiconductor layer;
a second electrode, covered on at least part of a surface of the second semiconductor layer; and
an insulating layer, covered on an outside surface of the light-emitting layer or covered on the outside surface of the light-emitting layer as well as part of the surface of the first semiconductor layer and part of the surface of the second semiconductor layer, wherein
the first semiconductor layer, the second semiconductor layer, and the light-emitting layer form a sphere structure, and the first electrode, the second electrode, and the insulating layer form a spherical structure; and
the plurality of spherical vertical micro LEDs are arranged in the plurality of loading wells in one-to-one correspondence and form a micro-LED array;
a transparent connection circuit, coupled with first electrodes of the spherical vertical micro LEDs and a first port of the backplane to realize electrical connections between the first electrodes and the outside; and
a plurality of magnetic metal gaskets, arranged in the plurality of loading wells in one-to-one correspondence, wherein the plurality of magnetic metal gaskets are coupled with second electrodes of the spherical vertical micro LEDs and a second port of the backplane to realize electrical connections between the second electrodes and the outside.

15. The micro LED display panel of claim 14, wherein materials of the second electrode comprise a conductive magnetic material, and the second electrode has a magnetism opposite to that of a magnetic metal gasket in a loading well.

16. The micro LED display panel of claim 15, wherein the conductive magnetic material of the second electrode forms a patterned shape.

17. The micro LED display panel of claim 16, wherein the spherical vertical micro LED comprises an R-type LED, a G-type LED, and a B-type LED, and spherical structures of the R-type LED, the G-type LED, and the B-type LED are in different diameters.

18. A transfer method for a micro light-emitting diode (LED) display panel, comprising:
placing a plurality of spherical vertical micro LEDs in a suspension, wherein each of the spherical vertical micro LEDs comprises:
a first semiconductor layer;
a second semiconductor layer;
a light-emitting layer, disposed between the first semiconductor layer and the second semiconductor layer;
a first electrode, covered on at least part of a surface of the first semiconductor layer;
a second electrode, covered on at least part of a surface of the second semiconductor layer; and
an insulating layer, covered on an outside surface of the light-emitting layer or covered on the outside surface of the light-emitting layer as well as part of the surface of the first semiconductor layer and part of the surface of the second semiconductor layer, wherein
the first semiconductor layer, the second semiconductor layer, and the light-emitting layer forming a sphere structure, and the first electrode, the second electrode, and the insulating layer forming a spherical structure;
placing a backplane in the suspension to make the spherical vertical micro LEDs float above the backplane, wherein the backplane defines a plurality of loading wells which form a loading-well array, and each of the plurality of loading wells is provided with a magnetic metal gasket; wherein materials of the second electrode comprise a conductive magnetic material, and the second electrode has a magnetism opposite to that of the magnetic metal gasket in the loading well; and
wherein a magnetism between the second electrode and the magnetic metal gasket allows the spherical vertical micro LED to be adsorbed in the loading well to form a micro-LED array, to realize transfer of the spherical vertical micro LEDs.

19. The transfer method of claim 18, wherein the conductive magnetic material of the second electrode forms a patterned shape.

20. The transfer method of claim 19, wherein the spherical vertical micro LED comprises an R-type LED, a G-type LED, and a B-type LED, and spherical structures of the R-type LED, the G-type LED, and the B-type LED are in different diameters.
